(19) United States
(12) Patent Application Publication
(10) Pub. No.: US 2016/0078960 A1
(43) Pub. Date: Mar. 17, 2016

(54) METHOD AND APPARATUS FOR WRITING DATA TO NON-VOLATILE MEMORY

(71) Applicant: SanDisk Technologies Inc., Plano, TX (US)

(72) Inventors: Nian Yang, Mountain View, CA (US); Jianmin Huang, San Carlos, CA (US); Ting Luo, Sunnyvale, CA (US); Alexandra Bauche, San Jose, CA (US); Nagdi Tafish, Santa Clara, CA (US)

(21) Appl. No.: 14/485,097

(22) Filed: Sep. 12, 2014

(51) Int. Cl. G11C 16/34; G11C 11/56

(52) U.S. Cl. CPC G11C 16/3422; G11C 11/5635

(57) ABSTRACT

Devices and methods implemented therein are disclosed for storing data in memory pages of a non-volatile memory of the storage device. The device comprises a non-volatile memory, a reading circuit, a programming circuit and a read disturb detector. The non-volatile memory has an erased memory page comprising a plurality of multi-layer cells (MLCs). The reading circuit is configured to read a respective electric charge stored in each of the plurality of MLCs. The programming circuit is configured to store data in the plurality of MLCs at either one of a first storage density or a second storage density. The read disturb detector is configured to determine whether the erased memory page is read disturbed and if the erased memory page is read disturbed, cause the programming circuit to store data into the MLCs at the second storage density that is less than the first storage density.

### TECHNICAL FIELD

This application relates generally to writing data in a memory system. More specifically, this application relates to methods for verifying the status of non-volatile memory before writing data to the non-volatile memory.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Non-volatile memory systems, such as flash memory, are used in digital computing systems as a means to store data and have been widely adopted for use in consumer products. Flash memory may be found in different forms, for example in the form of a portable memory card that can be carried between host devices or as a solid state disk (SSD) embedded in a host device. These memory systems typically work with memory units called memory pages. The memory pages may consist of a set of memory storage units called memory cells.

As flash memory scales to smaller dimensions to provide higher storage capacity per unit area, writing or reading to one memory page disturbs the state of the other memory pages. The magnitude of the disturbance increases as the memory cells shrink in size, as memory pages increase in size (i.e., more memory cells per memory page) and as silicon process complexity increases. Methods are needed to intelligently detect and account for disturbed memory pages before writing data to such disturbed memory pages.

### SUMMARY

In order to address the need to improve utilization of read disturbed memory pages consisting of multi-level cells (MLCs), methods and apparatus are disclosed herein for storing data in the read disturbed memory pages at a reduced storage density.

According to one aspect, a method for writing data in a memory system having a non-volatile memory is disclosed. An erased memory page in the non-volatile memory is identified. The memory page comprises a set of X memory cells. Each memory cell is configured to store an integer number of bits, N. The memory page is configured to store X times N bits of data. The number of read disturbed memory cells in the memory page is determined. A read disturbed memory cell contains an electric charge between a first and second predetermined threshold. In response to determining that the number of read disturbed memory cells of the memory page exceeds a threshold number, X times M bits of data is written to the memory page, where M is an integer that is less than N and greater than 0.

According to another aspect, a method for writing data in a memory system is disclosed. The memory system comprises an erased memory page. The memory page has a set of multi-layer cells (MLCs). The set of MLCs have a first storage density. In response to receiving a request to store data, a number of MLCs in the set of MLCs that exceed a voltage threshold is determined. In response to determining that the number of MLCs exceeding the voltage threshold is above a threshold number of MLCs, a portion of the received data is stored in the set of MLCs at a second storage density that is less than the first storage density.

According to yet another aspect, a device comprising a non-volatile memory, a reading circuit, a programming circuit and a read disturb detector is disclosed. The non-volatile memory has an erased memory page comprising a plurality of multi-layer cells (MLCs). The reading circuit is configured to read a respective electric charge stored in each of the plurality of MLCs. The programming circuit is configured to store data in the plurality of MLCs at either one of a first storage density or a second storage density. The read disturb detector is configured to determine whether the erased memory page is read disturbed and if the erased memory page is read disturbed, cause the programming circuit to store data into the MLCs at the second storage density that is less than the first storage density.

Other features and advantages will become apparent upon review of the following drawings, detailed description and claims. Additionally, other embodiments are disclosed, and each of the embodiments can be used alone or together in combination. The embodiments will now be described with reference to the attached drawings.

### BRIEF DESCRIPTION OF THE DRAWINGS

FIG. 1 illustrates a block diagram of host and storage device according to one embodiment.

FIG. 2 is a block diagram of an example storage device that may implement methods described herein.

FIG. 3A illustrates an example physical memory organization of the memory in the storage device of FIG. 1.

FIG. 3B shows an expanded view of a portion of the physical memory of FIG. 2.

FIG. 4A illustrates the structure of an exemplary memory cell of an example non-volatile memory device that may be used to store one or more bits of data.

FIG. 4B illustrates the mapping of ranges of voltage levels developed across a 3-level MLC-type memory cell as a result of trapped electric charge to binary data.

FIG. 4C illustrates the mapping of ranges of voltage levels developed across a 2-level MLC-type memory cell as a result of trapped electric charge to binary data.

FIG. 4D illustrates the mapping of ranges of voltage levels developed across an SLC-type memory cell as a result of trapped electric charge to binary data.

FIG. 5 illustrates an exemplary memory block consisting of memory pages comprising 3-level MLC type memory cells.

FIG. 6 depicts exemplary histograms of the distribution of the trapped electric charges for the memory cells of an erased memory page consisting of 3-level MLC-type memory cells.

FIG. 7 is a flow diagram of an exemplary method for storing data in an erased memory page.

FIG. 8 is a flow diagram of another exemplary method for storing data in a memory page.

FIG. 9 is a block diagram of another example storage device that may implement methods described herein.

### DETAILED DESCRIPTION

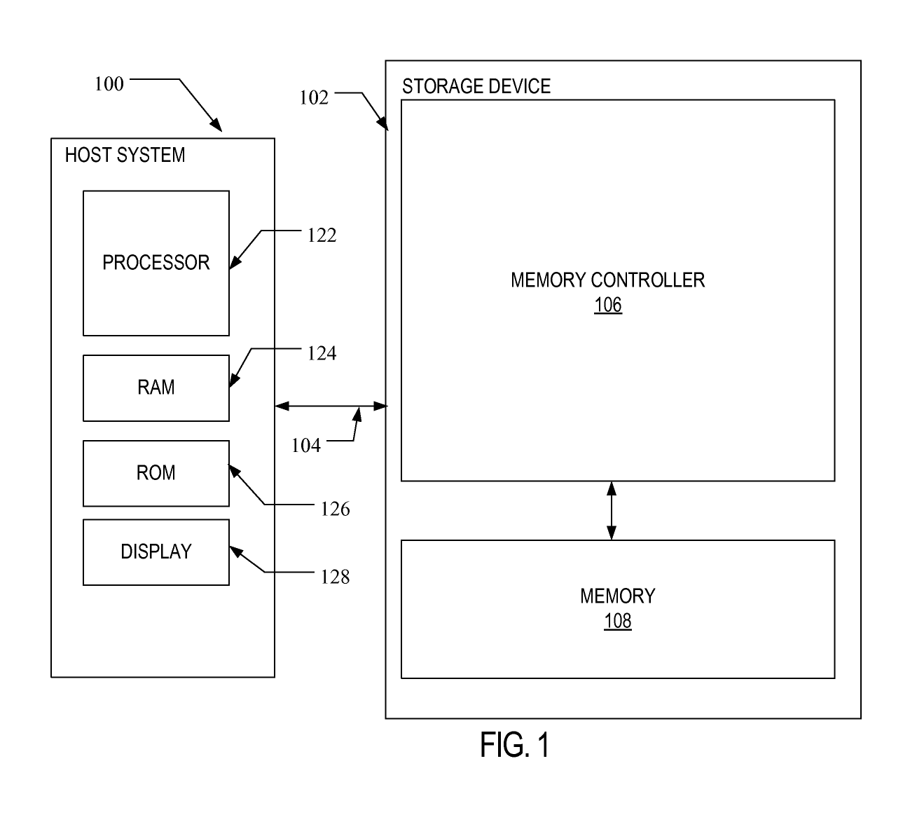

A system suitable for use in implementing aspects of the invention is shown in FIG. 1. A host device 100 stores data into, and retrieves data from, a storage device 102. The storage device 102 may be referred to as a memory system. The storage device 102 may be embedded in the host device 100 or may exist in the form of a card or other removable drive, such as a solid state disk (SSD) that is removably connected to the host device 100 through a mechanical and electrical connector conforming to an appropriate standard such as e-MMC, PCMCIA, CompactFlash or other known connector formats. The host device 100 may be any of a number of fixed or portable data generating devices, such as a personal computer, a mobile telephone, a personal digital assistant (PDA), or the like. The host device 100 communicates with the storage device over an input/output interface 104.

In an embodiment, the storage device 102 comprises a memory controller 106 and a memory 108. Memory 108 may include semiconductor memory devices that store data. The storage device 102 may be in the form of a portable flash drive, an integrated solid state drive or any of a number of known flash drive formats. In yet other embodiments, the storage device 102 may include only a single type of flash memory having one or more partitions.

Memory controller 106 operates to communicate data and program code back and forth between host device 100 and memory 108. The memory controller 106 may convert between logical addresses of data used by the host device 100 and physical addresses of memory 108 during programming and reading of data.

Typically, memory 108 is comprised of discrete storage units. The storage capacity or density of each storage unit may be specified as bits per unit storage unit. In an embodiment, memory controller 106 detects reduction in the storage capacity of the storage unit. The reduction in storage capacity is caused by the use of the storage device 102. In response to detecting a reduction in the storage capacity of one or more storage units, memory controller 106 stores data in the affected storage units at a reduced density.

As discussed in more detail below, the storage device 102 may include functions for memory management. In operation, the processor 110 may execute memory management instructions for operation of memory management functions. The memory management functions may control the assignment of the one or more portions of the memory 108 within storage device 102.

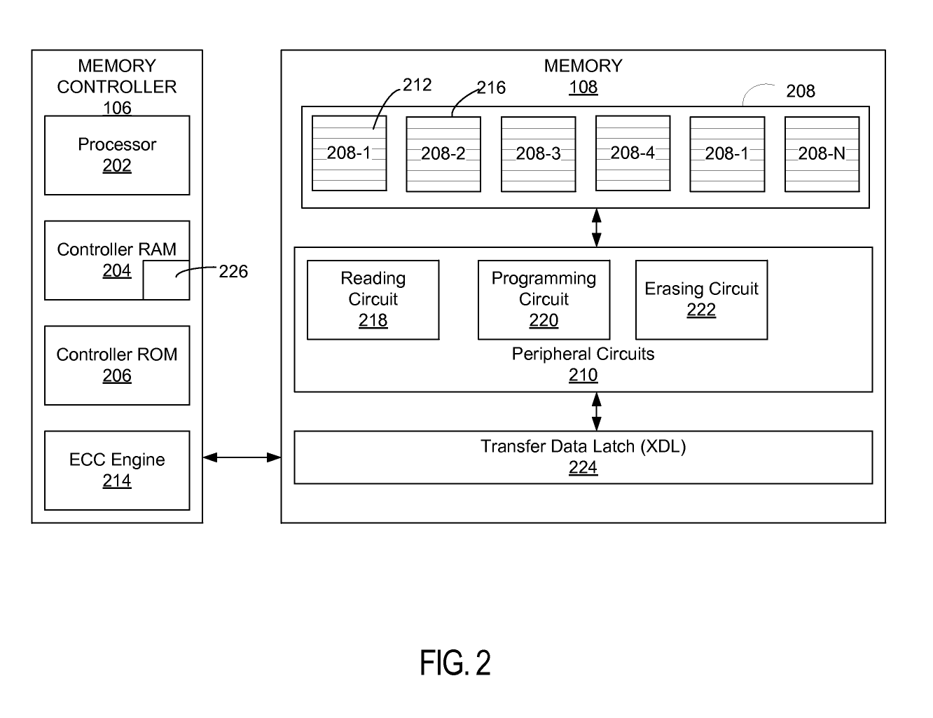

FIG. 2 is a detailed block diagram of an example memory system 200. In this embodiment, the example memory system 200 corresponds to the storage device 102 of FIG. 1. The memory system 200 comprises a memory controller 106 and memory 108.

By way of example and without limitation, in an embodiment, memory controller 106 includes a processor 202, controller RAM 204, controller ROM 206 and error correcting code (ECC) engine 208, in this embodiment. The processor 202 may comprise a microprocessor, a microcontroller, an application specific integrated circuit (ASIC), a field programmable gate array, a logical digital circuit, or other now known or later developed logical processing capability. Controller ROM 206 may store software instructions that processor 202 may execute to control the operation of storage device 102.

In an exemplary embodiment, memory 108 includes non-volatile memory 208, peripheral circuits 210 and a transfer data latch 224. Typically, a solid-state non-volatile memory retains information stored therein even if the storage device 102 is powered down or disconnected from host 100.

In an embodiment, non-volatile memory 208 comprises NAND flash memory. In this embodiment, non-volatile memory 208 is organized as N memory blocks 208-1 to 208-N. A memory block is organized as a set of memory pages or simply pages, memory page 212 for example. In this embodiment, a page is a smallest unit of writing in the memory 108 and a memory block is the smallest unit of erasing. Thus, data is typically programmed or stored on a page by page basis. However, erasing data programmed in a page requires erasure of all the pages in the memory block.

Each page consists of a set of single-level cell (SLC) or multi-level cell (MLC). A memory cell discussed with reference to FIG. 2 may correspond to a storage unit discussed with reference to FIG. 1. A SLC memory can store a single bit of data per cell. MLC memory can store multiple bits of data per MLC. For example, two-level MLC memory can store 2 bits of data per MLC, three level MLC memory can store 3 bits of data per cell and N level MLC memory can store N bits of data per cell. Typical sizes of memory pages are 16 Kilobytes (Kbytes). A memory block typically consists of hundreds of memory pages. In describing exemplary embodiments herein, the term “cell” is used to refer to both SLC and MLC. A memory cell can be in an erased state or a programmed state. A memory page with memory cells in an erased state may be referred to as an erased memory page. Data received from the host device 100 is typically programmed or stored in an erased memory page.

Both types of cells (SLC and MLC) store data by storing electric charge (charge). The amount of electric charge stored in a cell is representative of the data bit(s) stored in the cell. For example, in case of an erased SLC, no charge or an infinitesimal amount of electric charge is stored in the SLC and this uncharged state represents a bit value of 0. In contrast, a predefined amount of electric charge stored in an SLC, represents the bit value of 1. In the case of an N-level MLC, 2^{N} different predefined amounts of charge may be stored to represent anyone of the 2^{N} bits of data. For example, a three-level MLC is configured to store any one of eight amounts of electric charge values (2³=8). The number of different amounts of electric charge that may be stored in a memory cell may be referred to as the density of the memory cell. Thus a 3-level MLC is denser than a 2-level MLC and so on. Methods for storing data in memory page described herein, may determine the amount of electric charge stored in the erased memory cells of a memory page and based on the amount of electric charge measured, may store data in the memory page at a reduced density. Components of the storage device 102 read the amount of charge stored in a cell and translate the amount to a binary value.

In an embodiment, peripheral circuit 210 includes programming circuit 220, reading circuit 218, erasing circuit 222 and transfer data latch (XDL) 224. The XDL 224 functions as intermediate data storage between memory controller 106 and memory 108. When instructed by host 100 to write data to memory 108, memory controller 106 writes data to XDL 224. The programming circuit 220 then writes the data from XDL 224 to the specified memory block and page. By way of example and without limitation, the size of the XDL is equal to the size of a page. Similarly, when instructed to read data from a specified memory chunk or page, reading circuit 218 reads data from the specified memory chunk or page into the XDL 224 and memory controller 106 transfers the read data from the XDL 224 to controller RAM 204.

In an embodiment, the reading circuit 218 of FIG. 2 translates the amount of charge stored in a memory cell to a binary representation of the data corresponding to the amount of charge stored in the cell. By way of example and without limitation, the reading circuit 218 may include current to voltage convertors, amplifiers and analog to digital convertors.

The programming circuit of FIG. 2 translates the binary representation of data received from host device 100 into programming voltages and periods. The programming circuit applies these programming voltages for the periods programming periods to memory cells to cause the memory cells to store electric charge. The amount of stored electric charge is representative of the binary representation of the received data.

In an embodiment, the memory controller 106 maintains a logical to physical address table 226 in controller RAM 204. An entry in the table 226 includes a reference to a memory page. Thus, the logical to physical address table 226 may comprise an array of references to memory pages. One format of an entry in the table may comprise a reference to the memory block associated with the memory page and an index or offset into the memory block.

The host device 100 when requesting a write of data specifies a logical address. In response to receiving a request from host device 100 to write data to a logical address, processor 202 may utilize the logical address as an index into the logical to physical address table 226 and identify the memory page and the memory block corresponding to the logical address. The processor 202 may determine if the identified memory page is already written to (not erase). In response to determining that the memory page is not erased, processor 202 may locate a new memory page that has not been written to and write the received data to the new memory page. Separately, processor 202 may update the entry in the logical to physical address table 226 corresponding to the logical address with a reference to the memory block associated with the new memory page.

As is explained in the following paragraphs, the processes of reading and writing data to other memory pages in the memory block may cause some or all of the memory cells in the erased memory page to accumulate electric charge. This causes the memory cells to no longer be in the erased state. In an exemplary embodiment, before writing data to the identified erased memory page, memory controller 102 may determine if the memory cells in the erased memory page are in the erased state i.e. there is no stored electric charge.

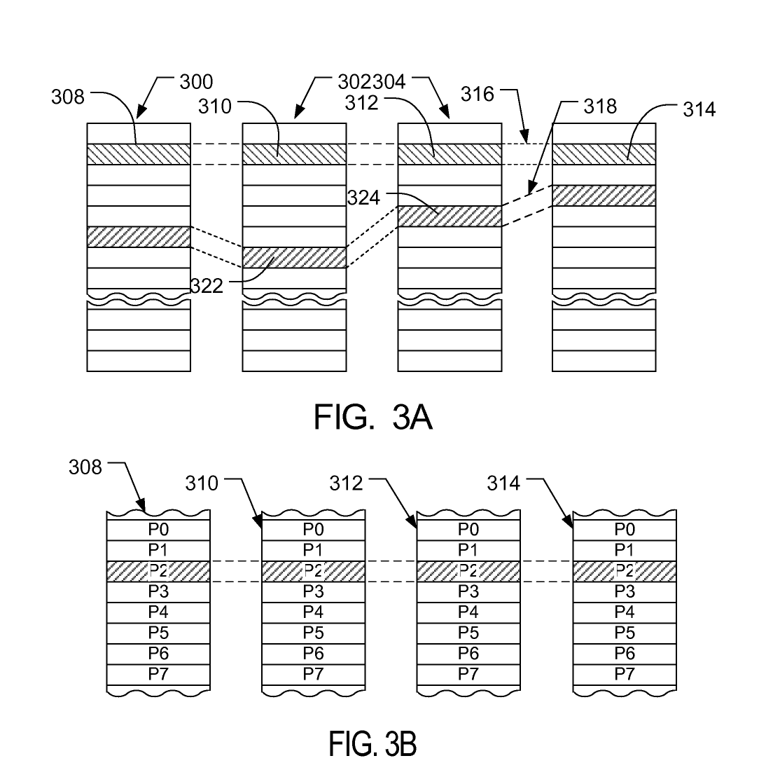

Referring to FIG. 3A, memory 108 (e.g. SLC and MLC flash respectively) may be arranged in blocks of memory cells. In the example of FIG. 3A, four planes or sub-arrays 300, 302, 304 and 306 memory cells are shown that may be on a single integrated memory cell chip, on two chips (two of the planes on each chip) or on four separate chips. The specific arrangement is not important to the discussion below and other numbers of planes may exist in a system. The planes are individually divided into blocks of pages shown in FIG. 3A by rectangles, such as pages 308, 310, 312 and 314, located in respective planes 300, 302, 304 and 306. There may be dozens or hundreds of blocks in each plane. Pages may be logically linked together to form a memory block that may be erased as a single unit. For example, pages 308, 310, 312 and 314 may form a first memory block 316. The pages used to form a memory block need not be restricted to the same relative locations within their respective planes, as is shown in the second memory block 318 made up of pages 320, 322, 224 and 226.

A memory block 302 is illustrated in FIG. 3B is formed of one physical page for each of the four pages 308, 310, 312 and 314. The blocks disclosed in FIGS. 3A-3B are referred to herein as physical blocks because they relate to groups of physical memory cells as discussed above. As previously discussed and as used herein, a logical block is a virtual unit of address space defined to have the same size as a page. Each logical block includes a range of logical block addresses (LBAs) that are associated with data received from a host 100. The LBAs are then mapped to one or more memory pages in the storage device 102 where the data is physically stored.

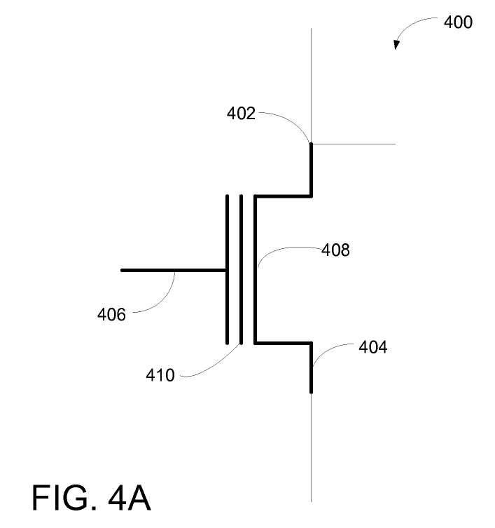

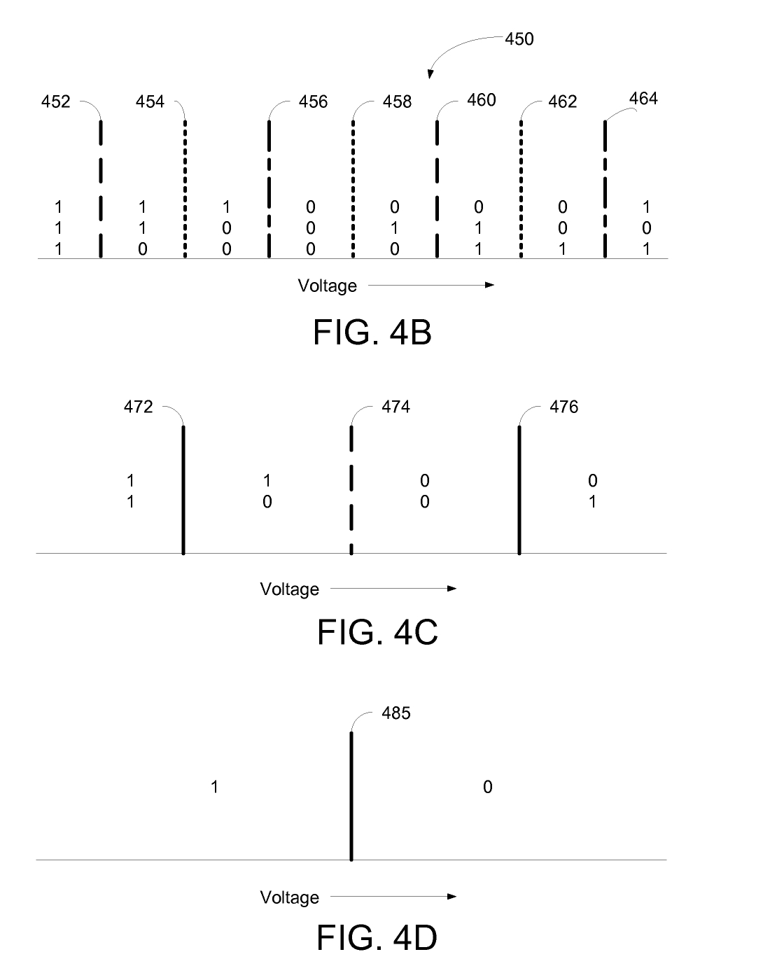

FIG. 4A illustrates the structure of an exemplary memory cell 400 that may be used to store one or more bits of data. In an embodiment, memory cell 400 comprises a floating gate transistor (FGT). In this embodiment, memory cell 400 comprises a source electrode 402, a drain electrode 404, a control gate electrode 406, substrate 408 and a floating gate 410.

Programming memory cell 400 consists of causing memory cell 400 to store or trap a pre-defined amount of electric charge. The amount of electric charge caused to be trapped corresponds to the binary value of the data being programmed. Memory cell 400 stores electric charge by trapping electric charge on the floating gate 410. By causing appropriate voltage levels to be applied to source electrode 402, drain electrode 404 and control gate electrode 406, memory cell 400 may be programmed to store different amounts of electric charge. In a 3-level MLC-type cell, the amount of stored electric charge corresponds to a respective one of eight binary values. Performance of the steps required to program a memory cell may be performed by programming circuit 200 (FIG. 2), in an embodiment. Operation of the programming circuit 200 may be controlled by memory controller 106, in this embodiment.

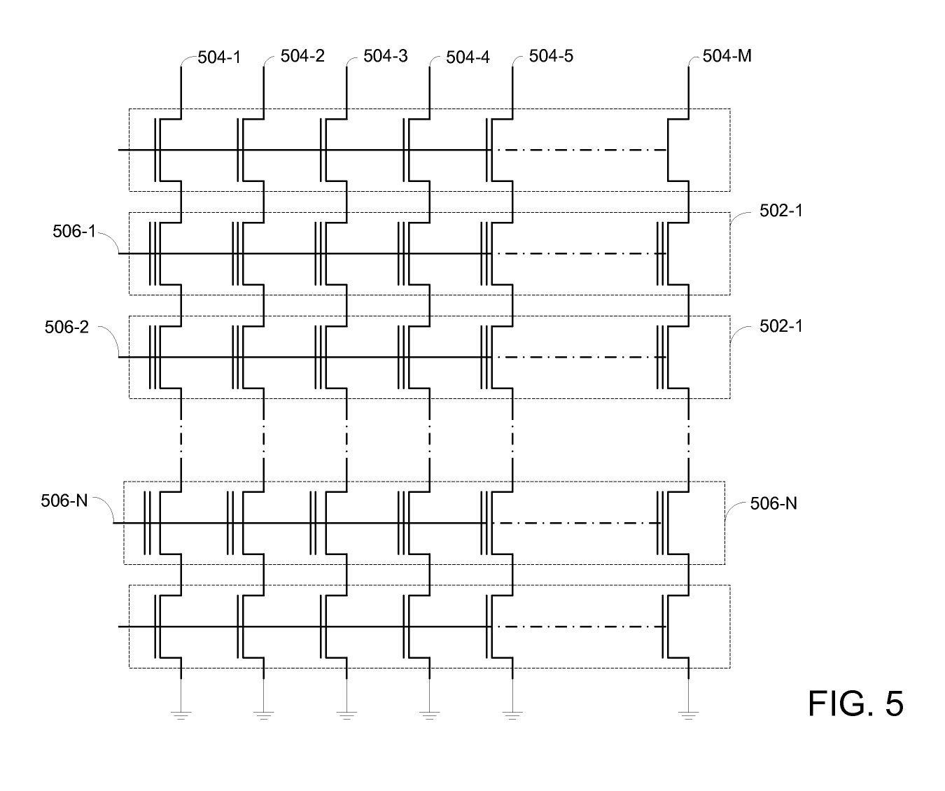

In addition to expressly causing charge to be stored in memory cell 400 by applying the appropriate programming voltages, memory cell 400 may also accumulate charge whenever voltage is only applied to source electrode 402. As is explained in detail with reference to FIG. 5, this occurs when a memory cell in series with memory cell 400 is read. Thus, even when memory cell 400 is erased i.e. all charge is removed, over time memory cell 400 may accumulate charge when memory cells in series with it are read. The memory cell 400 is termed read-disturbed.

In an erase state, floating gate 410 stores no electric charge. Erasing memory cell 400 consists of applying appropriate voltage levels to source electrode 402, drain electrode 404 and control gate electrode 406 to remove any stored electric charge. Erasing circuit 222 may perform the required steps to erase memory cell 400, in an embodiment.

To read the amount of electric charge stored in memory cell 400, a read voltage, V_{cgr}, is applied to the source electrode 402. The drain electrode 404 and control gate electrode 406 are simultaneously connected to ground. Finally, the current flowing between the source electrode 402 and drain electrode 404 through substrate 408 is measured. Alternatively, the voltage developed across the source electrode 402 and drain electrode 404 may be measured. The magnitude of the measured current or the measured voltage corresponds to the amount of electric charge stored in memory cell 400. In the erased state, no charge is trapped at the floating gate 410 and therefore the path between the source electrode 402 and drain electrodes 404 is non-conductive. Consequently a high voltage is detected across the source electrode 402 and drain electrode 404 and no current flow is detected. This high voltage may correspond to a logic level of 0.

If memory cell 400 is programmed, the magnitude of the voltage developed across the source electrode 402 and drain electrode 404 or the magnitude of current flowing through the source electrode 402, substrate 408 and drain electrode 404 corresponds to the amount of charge trapped at the floating gate 410. In a 3-level MLC, the magnitude of the voltage is correlated to one of the eight possible binary values. Application of the read voltage may be performed by reading circuit 218, in an embodiment. In an embodiment, reading circuit 218 may measure the voltage developed across the source electrode 402 and the drain electrode 404. Reading circuit 218 may translate the measured voltage to a binary value representation of the data programmed in memory cell 400. In another embodiment after applying the read voltage, reading circuit 218 may measure the current flowing through the source electrode 402 and the drain electrode 404. Reading circuit 218 may translate the measured current to a binary value representation of the data programmed in memory cell 400. Other methods of measuring the electric charge stored at floating gate 410 are contemplated.

Graph 450 of FIG. 4B illustrates the relationship between the amount of charge stored or trapped at the floating gate 410 of a 3-level MLC memory cell and the corresponding binary value as translated by the reading circuit 218, in an embodiment. Voltage levels representative of the electric charge stored at floating gate 410 are depicted on the X-axis.

For example, in case of a level 3 MLC-type cell, reading circuit 218 may translate a measured voltage level that is below voltage 452 to a binary value of 111 i.e. the erased state. Memory controller 102 may invert (logical NOT) the binary value 111 to logical value 0. Reading circuit 218 may translate a measured voltage level that is between voltage 452 and voltage 454 to a binary value of 110 and so on. Exemplary voltage level ranges and their corresponding binary and logical representations are tabulated in Table 1, where the numbers used in the voltage range column correspond to the reference numbers of the relative voltage levels shown in FIG. 4B and are not absolute voltage numbers. These exemplary voltage levels may be referred to as threshold voltages. The voltage ranges in Table 1 are representative of the amount of electric charge stored at floating gate 410 of memory cell 400, for example. Table 1 may be referred to as a mapping table and the process of translating a range of voltage levels into a binary value using Table 1 may be referred to as mapping.

TABLE 1

| Voltage Range | Binary Value | Logical Value |
|---|---|---|
| <452 | 111 | 000 |
| >452 and <454 | 110 | 001 |
| >454 and <456 | 100 | 011 |
| >456 and <458 | 000 | 111 |
| >458 and <460 | 010 | 101 |
| >460 and <462 | 011 | 100 |
| >462 and <464 | 001 | 110 |
| >464 and <466 | 101 | 010 |

Table 1 may also be used to program or store the appropriate amount of charge in the memory cell. For example, to program a binary value of 100 into a memory cell, programming circuit 220 may apply voltages that cause the memory cell to trap electric charge that will produce a voltage level between 454 and 456.

Graph 470 of FIG. 4C illustrates the relationship between the amount of charge stored or trapped at the floating gate 410 of a 2-level MLC memory cell and the corresponding binary value as translated by the reading circuit 218, in an embodiment. Voltage levels representative of the electric charge stored at floating gate 410 are depicted on the X-axis.

For example, in case of a 2 level MLC-type cell, reading circuit 218 may translate a measured voltage level that is below voltage 472 to a binary value of 111 i.e. the erased state. Reading circuit 218 may translate a measured voltage level that is between voltage 472 and voltage 474 to a binary value of 10, a measured voltage level that is between voltage 474 and voltage 476 to a binary value of 01, and a measured voltage level that is above voltage 476 to a binary value of 00. As previously explained the memory controller 102 may invert these binary values to generate corresponding logical values, in an embodiment. Exemplary voltage level ranges for a 2-level MLC memory cells and their corresponding binary and logical representations are tabulated in mapping Table 2, where the numbers used in the voltage range column correspond to the reference numbers of the relative voltage levels shown in FIG. 4C and are not absolute voltage numbers.

TABLE 2

| Voltage Range | Binary Value | Logical Value |
|---|---|---|
| <472 | 11 | 00 |
| >472 and <474 | 10 | 01 |
| >474 and <476 | 01 | 11 |
| >476 | 00 | 11 |

Graph 480 of FIG. 4D illustrates the relationship between the amount of charge stored or trapped at the floating gate 410 of an SLC memory cell and the corresponding binary value as translated by the reading circuit 218, in an embodiment. Voltage levels representative of the electric charge stored at floating gate 410 are depicted on the X-axis. The reading circuit translates or interprets a measured voltage that is less than 485 to a binary value of 1 and a measured voltage that is greater than or equal to threshold voltage 485 to a binary value of 0. Exemplary voltage level ranges for an SLC memory cell and corresponding binary and logical representations are tabulated in mapping Table 3, where the number used in the voltage range column corresponds to the reference number of the relative voltage level shown in FIG. 4C and is not an absolute voltage number. Mapping tables 1, 2 and 3 may be stored in controller ROM 206, in an embodiment.

TABLE 3

| Voltage Range | Binary Value | Logical Value |
|---|---|---|
| <485 | 1 | 0 |
| >485 | 0 | 1 |

FIG. 5 illustrates an exemplary memory bock 500. Memory block 500 may correspond to memory block 208-1, in an embodiment. As previously explained, memory block 500 consists of memory cells organized as memory pages 502-1 to 502-N. Referring to FIG. 2, a memory page 502-1 may correspond to memory page 212 of memory block 208-1. By way of example and without limitation, the memory cells may correspond to the 3 level MLC memory cell 400 of FIG. 4A, in an embodiment. Embodiments with memory blocks having N-level MLC memory cells where N is greater than 3 or less than 3 are contemplated.

To write data or program data to an erased memory page, memory page 502-1 for example, the programming circuit 220 applies appropriate voltages to the bit lines 504-1 to 504-M. As previously explained an erased memory cell has no trapped electric charge and corresponds to logic 0. Therefore, if logic 0 is to be programmed to a memory cell, a programming voltage is not applied to the corresponding bit line, in an embodiment. Approximately simultaneously, the appropriate write voltage is applied via word line 506-1 to the control gates of the memory cells of memory page 502-1. Separately, the control gates 512 and 514 of switches 508 and 510 respectively are enabled to allow the programming voltages to appear across the memory cells of the memory page 502-1 that is being programmed. In an embodiment, the time period for which a programming voltage is applied to a bit line determines the amount of charge that is trapped at a floating gate and consequently the representative bit values that is stored in the memory cell.

Reading a memory page, page 502-1 for example, consists of reading circuit 218 applying a read voltage to word lines 506-2 to 506-N for a short duration. Approximately simultaneously, a voltage is applied to the bit lines 504-1 to 504-M and the control gates control gates 512 and 514 of switches 508 and 510. The voltage developed across the bit lines is then measured. If a memory cell in memory page 502-1 is erased or at logic 0, as previously explained, the memory cell is not conductive and consequently reading circuit 218 detects a high voltage across the corresponding bit line. If a memory cell is programmed, it is conductive. The degree of conductivity varies based on the amount of charge stored in the memory cell. Consequently reading circuit 218 detects a voltage across the corresponding bit line that is lower in magnitude than the voltage applied to the bit line. As previously explained this voltage corresponds to the amount of charge stored in the memory cell which in turn is representative of the data stored in the memory cell.

Application of the read voltages to an erased memory page, 506-2 for example, when reading another memory page, 506-1 for example, causes erased memory cells in the erased memory page to become momentarily conductive. Application of the read voltage causes a small of electric charge to migrate towards the floating gate of the memory cells of the erased memory page. Some of the electric charge remains trapped at the floating gate of the erased memory cells of the erased memory page after the removal of the read voltages. Over time repeated reads of other memory pages causes increasing amounts of electric charge to be trapped at the floating gate of the erased memory cells of the erased memory page. As a result, because of the trapped electric charge an erased memory cell may develop a voltage that exceeds some or all of the threshold voltage levels depicted in Table 1. Thus, although the memory page is considered erased, some or all of the memory cells may store electric charge that represents non-zero data. An erased memory cell that stores electric charge because of read operations performed on other memory pages may be referred to as a read disturbed memory cell. Similarly, an erased memory page that contains one or more read disturbed memory cells may be referred to as a read disturbed memory page.

In an embodiment, before writing to an erased memory page, the number of read disturbed cells in the memory page and the degree of disturbance may be determined. The degree of disturbance relates to the amount of electric charge trapped in an erased memory cell. In this embodiment, based on the number of read disturbed memory cells and the amount of electric charge trapped in the read disturbed cells of the erased memory page, a lesser amount of data may be programmed or stored in the memory page.

Referring to FIGS. 4B and 4C, where a read disturbed 3-level MLC memory cell with electric charge that produces a voltage level that is between voltage thresholds 452 and 454 corresponds to a binary value of 110, the same voltage level is below the voltage threshold 472 that corresponds to a binary value of 11, the erased state. Similarly, referring to FIGS. 4C and 4D, where a read disturbed 2-level MLC memory cell with electric charge that produces a voltage level that is between voltage thresholds 472 and 474 corresponds to a binary value of 10, the same voltage level is below the voltage threshold 485 that corresponds to a binary value of 1, the erased state for an SLC memory cell.

The overlap between erased states and threshold voltages may be exploited in an embodiment, to reuse memory page with read disturbed memory cell having N-level as memory cells having N−1-levels. In this embodiment, prior to programming data into an erased memory page, memory controller 106 and reading circuit 218 may determine the number of read disturbed memory cells in the erased 3-level memory page that exceed the threshold voltage 452. If a pre-defined percentage of the 3-level memory cells of the memory page are read disturbed with electric charge that produces a respective voltage level that is greater than voltage level 452 (Table 1) and less than voltage level 454, memory controller 106 may re-characterize the memory page as consisting of 2-level MLC memory cells. For example, if 0.1% of the memory cells of an erased memory page consisting of five hundred and twelve (512) 3 level MLC memory cells are read disturbed with electric charge that produces a voltage that is greater than voltage level 452 (Table 1) but less that voltage level 454, in this embodiment, memory controller 106 programs 512×2 bits of data in the memory page. The pre-defined percentage may correspond to a fraction of the memory cells in the memory that are determined to be read disturbed.

Similarly, if a pre-defined percentage of the memory cells of a memory page are read disturbed with electric charge that produces a voltage that is greater than voltage level 454 (Table 1) but is less that voltage level 456, in an embodiment, memory controller 106 re-characterizes the memory page as a SLC type memory and stores 512×1 bits of data in the memory page. Finally, if a pre-defined percentage of the memory cells of a memory page are read disturbed with electric charge that is greater than voltage level 456 (Table 1) but is less that voltage level 456, in an embodiment, memory controller 106 re-characterizes the memory page as unusable and marks it accordingly.

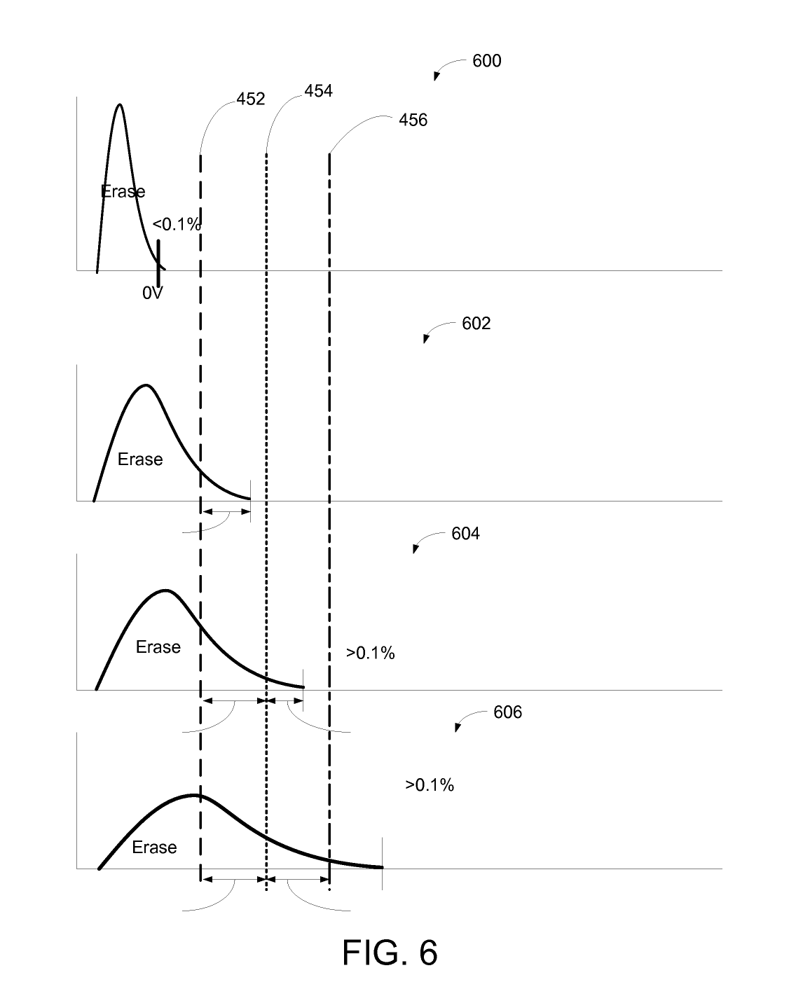

Graphs 600, 602, 604 and 608 depicted in FIG. 6 are histograms of the distribution of the trapped electric charges for the memory cells of an erased memory page consisting of 3-level MLC-type memory cells, 502-2 for example. The histograms are frequency distributions of the measured voltage level for the erased memory cells of the memory page. The number of memory cells is depicted on the vertical axis and the measured voltage level is depicted on the horizontal. The area under the curves 602, 622, 642 and 662 is the total number of memory cells in the memory page. Superimposed on the histogram are the threshold voltage levels from Table 1.

Graph 600 represents the histogram of an undisturbed erased memory page. None of the erased memory cells have trapped electric charge that produces a voltage level above threshold voltage level 452 (FIG. 4B). Consequently when read, reading circuit 218 will translate the voltage levels measured across all the memory cells as a 111 or logic 0.

Graphs 602, 604 and 608 represent histograms of disturbed erased memory pages. Referring to graph 602, a subset of the memory cells of the erased have trapped electric charges that produce measured voltages that exceed voltage threshold 452. Thus even though the memory cells belong to a memory page that is erased, reading circuit 218 will translate the measured voltages from the subset of the memory cells to a binary value of 110 (Table 1). If the number of memory cells in this subset exceeds a threshold, for example 0.1% of the total memory cells, in an embodiment, memory controller 106 may utilize the erased memory page as a 2-level MLC memory page to store data.

Referring to graph 604, a first subset of the memory cells of the erased memory page has trapped electric charges that produce measured voltages that exceed voltage threshold 452. A second subset of the memory cells of the erased memory page has trapped electric charges that produce measured voltages that exceed voltage threshold 454. Thus even though the memory cells belong to a memory page that is erased, reading circuit 218 will translate the measured voltages from the first subset of the memory cells to a binary value of 110 (Table 1) and will translate the measured voltages from the second subset of the memory cells to a binary value of 100 (Table 1). If the number of memory cells in the second subset exceeds a threshold, for example 0.1% of the total memory cells, in an embodiment, memory controller 106 may utilize the erased memory page as an SLC memory page to store data.

Referring to graph 608, a first subset of memory cells of the erased memory page has trapped electric charges that produce measured voltages that exceed voltage threshold 452. A second subset of the memory cells of the erased memory page has trapped electric charges that produce measured voltages that exceed voltage threshold 454. A third subset of the memory cells of the erased memory page has trapped electric charges that produce measured voltages that exceed voltage threshold 456. Thus even though the memory cells belong to a memory page that is erased, reading circuit 218 will translate the measured voltages from the first subset of the memory cells to a binary value of 110 (Table 1), the measured voltages from the second subset of the memory cells to a binary value of 100 (Table 1), and the measured voltages from the second subset of the memory cells to a binary value of 000 (Table 1). If the number of memory cells in the third subset exceeds a threshold, for example 0.1% of the total memory cells, in an embodiment, memory controller 106 may mark the memory page as unusable and identify another erased memory page to store data received from the host 102, for example.

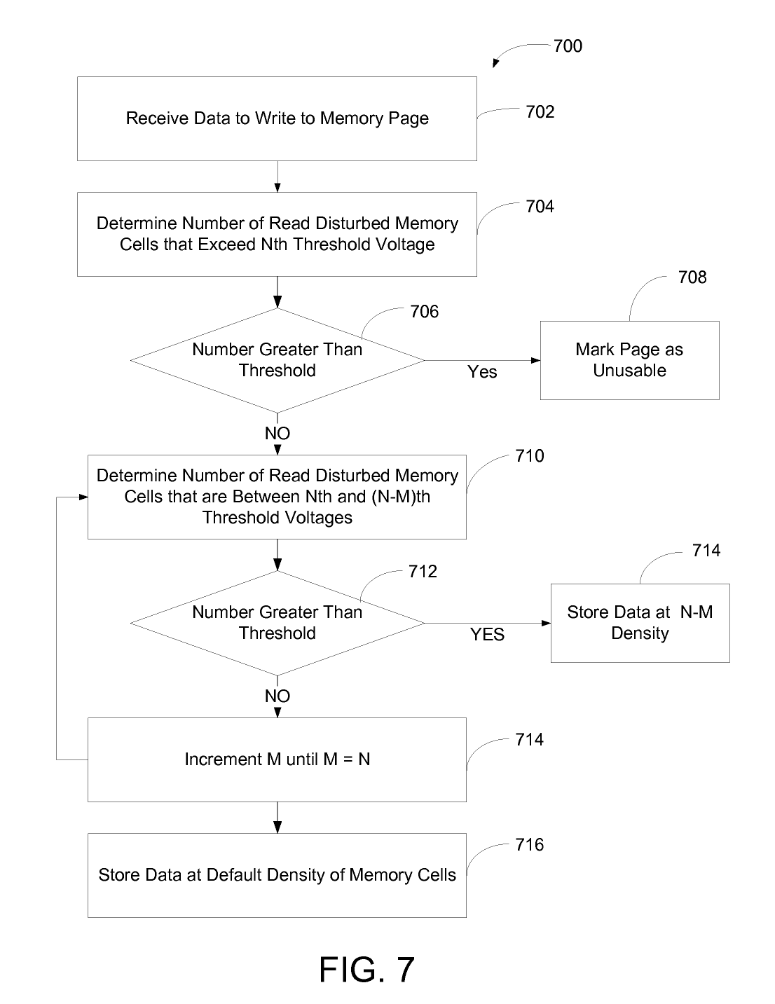

FIG. 7 is a flow diagram of an exemplary method 700 for storing data in an erased memory page. The data may be received from host device 100. Functionality associated with the several blocks of FIG. 7 may be implemented by software, hardware or any combination therefore.

At block 702, in response to receiving data to be stored in flash memory 108, memory controller 106 of storage device 102 may identify an erased memory page, 508-2 of FIG. 5 for example, in memory 108. By way of example and without limitation, in the following discussion, memory pages of memory 108 consist of 3-level MLC-type memory cells. Implementation of the method in a storage device with N-level MLC-type memory cells is contemplated. In an embodiment the data may be received by memory controller 106 from host 100. In an embodiment, at block 702, memory controller 106 may retrieve mapping table data, Tables 1, 2 and 3 for example, from controller ROM 206.

At block 704, controller 106 may determine the number of read disturbed memory cells in the identified erased memory page. As previously discussed, erased memory cells store a binary value of 0. In an embodiment, to determine the number of read disturbed cells, controller 106 may instruct the reading circuits 218 to read the data from the memory cells of the erased memory page. From the read data, controller 106 may identify the number and the location of non-zero bits for each memory cell. Based on the number and the location of non-zero bits, controller may determine the numbers of read disturbed memory cells that exceed one or more of the voltage thresholds of Table 1.

In an embodiment, controller 106 may maintain N counters that are initialized to 0. If the measured voltage for a memory cell is greater than the N^{th} voltage threshold, voltage threshold 456 for example in case of a 3-level memory cell, controller 106 may increment the first counter. The measured voltages for each of memory cells may be compared with the N^{th} voltage threshold. The N^{th} counter may be incremented each time a voltage level exceeding the N^{th} voltage threshold is detected.

At block 706, the value of N^{th} counter may be compared with a threshold. Of course, the value of the N^{th} counter corresponds to the number of memory cells with read disturb voltages that exceed the highest threshold voltage, voltage threshold 456 for example. This threshold may correspond to a percentage of the total number of memory cells in the memory page. An exemplary threshold may be 0.1%.

At block 706, in an embodiment, the value of N^{th} counter may be divided by the total number of memory cells in the memory page to determine a percentage of memory cells with read disturbed voltages that exceed the highest threshold voltage, voltage threshold voltage 456 for example.

If the percentage of read disturbed memory cells is greater than or equal to the threshold, in an embodiment at block 708, the memory page may be marked an unusable and the program flow may branch to 702. At block 702 a new erased page may be identified. If however the percentage of read disturbed memory cells is less than the threshold, program flow conditionally branches to block 710. In another embodiment, if the percentage of read disturbed memory cells is greater than or equal to the threshold default data may be stored in the memory page and the memory page may be subsequently erased to reclaim it for storage. Erasing the memory page removes the electric charge caused by the read disturbance.

At block 710, the respective measured voltage levels for each of the memory cells may be compared with the N^{th} voltage threshold and the (N−M)^{th} voltage threshold where M is initialized to be N−1, voltage threshold 454 for example. If a measured voltage level for a memory cell is lesser than the N^{th} voltage threshold and greater than the (N−M)^{th} voltage threshold, controller 106 may increment the next counter.

At block 712, the value of the next counter may be divided by the total number of memory cells in the memory page to determine a percentage of memory cells with read disturbed voltages that exceed the next highest threshold voltage, voltage threshold 454 for example. If the percentage exceeds a threshold percentage or fraction, at block 714, a portion of data may be stored in the memory cells at an N−M density. The program flow may branch to 702. At block 702 a new erased page may be identified to store the remained portion of the data. If the percentage does not exceed the threshold percentage or fraction, program flow may branch to 716.

At block 716, the value of M is decremented and the method steps of blocks 710 and 712 are repeated. M is iteratively decremented until M is equal to zero. If M reaches zero, data is stored at the default density of the memory cells and the program exits.

Because data is stored at a reduced density at block 714, in an embodiment, the quantum of data received from the host device 100 may exceed the storage capacity of the memory page at the reduced density. Memory controller 106 may identify another erased memory page and repeat the process to store the remaining data. For example, if a memory page consists of 100 3-level memory cells, at the default storage density of 3 bits per cell, the memory page can store 300 bits of data. At the reduced density of 2 bits per cell, the memory page can store 200 bits of data. If the quantum of data received from the host device was 256 bits, only 200 bits of the 256 bits may be stored at blocks 714. Memory controller 106 may identify another erased block after completing the storage of 200 bits of data at block 716. The remaining 56 bits may be stored in the identified erased block.

The program flow of method 700 may be arranged differently in other embodiments. For example, in another embodiment, controller 106 may instruct the reading circuit 218 to read the voltage level of a memory cell of the memory page 508-2. The voltage level may be iteratively compared with the different threshold voltage. The corresponding counter may be incremented when it is determined that the measured voltage level for the memory cell is between two voltage thresholds. Controller 106 may iteratively repeat the process for all of the memory cells. At the conclusion of the process, the values of the counter may represent a histogram or frequency distribution of the measured voltage levels. Based on the respective values of the counters, controller 106 may store data at the appropriate density. For example, if the value of the N^{th} counter exceeds the threshold percentage, the memory page may be marked unusable. If however, the sum of values of the N^{th} counter and (the N−1)^{th} counter exceed the percentage threshold, the data may be stored at the (N−(N−1)) density. If not, the sum of values of the N^{th} counter, (the N−1)^{th} and (the N−2)^{th} counter may be computed. If the sum exceeds the percentage threshold, the data may be stored at the (N−(N−2)) density.

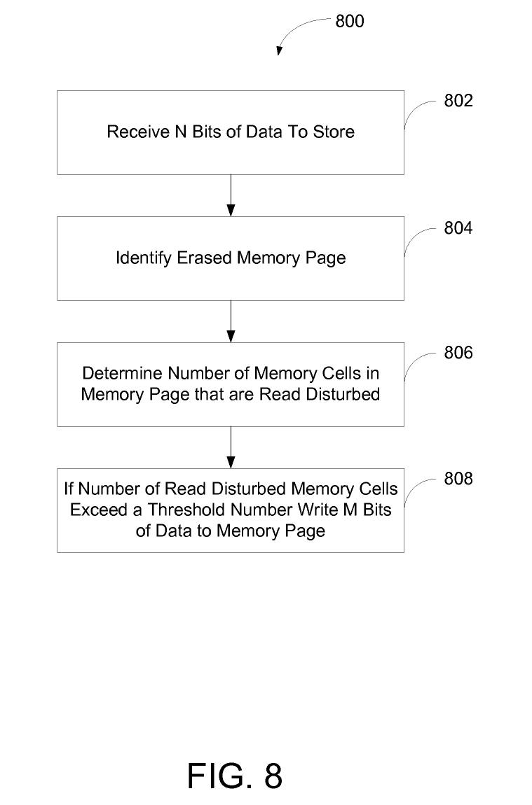

FIG. 8 is a flow diagram of another exemplary method 800 for storing data into a storage device 102, for example. The data may be received from host device 100. Functionality associated with the several blocks of FIG. 7 may be implemented by memory controller 106 by means of software, hardware or any combination therefore.

At block 802, memory controller 106 may receive n bits of data to store data into storage device 102. The received data may be associated with a logical block address (LBA). At block 804, memory controller 106 may identify an erased memory page, memory page 212 for example. The identified may consists of MLCs. The memory page 212 may have been previously erased, in an embodiment. As previously described a memory page has a default storage density which may correspond to the number of levels of the MLC and the number of MLCs in a memory page. For example, if a memory page comprises 256 3-level MLCs, the storage density of the memory page is 256 times 3.

At block 806, memory controller 106 may determine a number of read disturbed MLCs in the identified memory page. For example, at block 806 controller 106 may instruct the reading circuit 218 to read the respective electric charge stored in each of the number MLCs in the memory page. Typically, as previously discussed, an erased MLC should have an electric charge close to 0 coulombs. However, the previously detailed read disturb effects caused when other memory pages are read may cause some of the erased MLCs in the erased memory page to store a finite amount of electric charge. This finite electric charge may correspond to a non-zero or non-erased state. Controller 106 may compare the respective read electric charge for the MLCs with a threshold voltage to determine if one or more of the MLCs are read-disturbed.

In another embodiment, at block 806 controller 106 may instruct the reading circuit 218 to read data values stored in each of the MLCs. In this embodiment, reading circuit 218 may read the electric charge stored in each of the MLCs of the memory page and translate the read electric charge to a respective logical or binary value. For example, in case of a 3-level MLC, reading circuit 218 may use a table similar to table 1 to perform the translation. In this embodiment, controller 106 may compare the read data values with binary value 0 to determine if an MLC is read-disturbed.

At block 808, controller 806 may determine the number of read disturbed memory cells and the extent to which the memory cells are read-disturbed. If the number of read disturbed memory cells exceeds a threshold number, controller 106 may cause the programming circuit to store data in the MLCs at a lower storage density. In case of 3-level MLCs, data may be stored at a density corresponding to a 2-level MLC or an SLC. Thus instead of storing 256 times 3 bits of data in a memory page comprising 256 3-level MLCs, 256 times 2 bit of data or even 256 times 1 bits of data may be stored.

As previously described the selected storage density depends on the extent to which the memory cells are read-disturbed. In some instances, the accumulated charge on certain MLCs may exceed a value corresponding to binary 111, in case of a 3-level cell. If the number of such cells exceeds a second threshold, the memory page may be erased prior to storing data or a second erased memory page may be selected and the process may be repeated to determine the extent to which the second erased memory page is read disturbed.

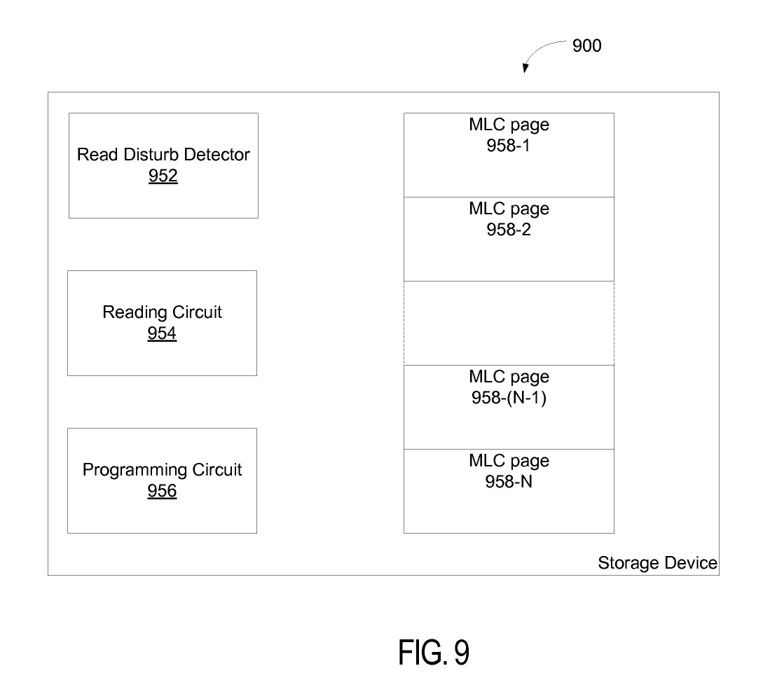

FIG. 9 is a block diagram of another exemplary memory system 900. In this embodiment, the example memory system 950 corresponds to the storage device 102 of FIG. 1. The memory system 950 comprises a read disturb detector 952, reading circuit 954, programming circuit 956 and memory 958.

Memory 958 comprises a set of MLC type memory pages 958-1 to 958-N. Some or all of the memory pages 958-1 to 958-N may be in an erased state. As previously discussed. Some of the MLCs in an erased memory page may accumulate an electric charge causing them to not be in an erased state.

The reading circuit 954, in an embodiment, is configured to read the electric charge stored in each of the MLCs in a memory page. In an exemplary embodiment, the reading circuit 954 may report a respective binary data value corresponding to the read electric charge from each of the memory cells. Typically, the reading circuit may include multiplexors, analog to digital convertors, amplifiers, level shifters, current to voltage convertors etc.

The programming circuit 956 is configured to write data to the MLCs in an erased memory. The programming circuit may include amplifiers, digital to analog convertors, decoders etc.

The read disturb detector 952 is configured to determine if one or more of the MLCs in an erased memory cells are read disturbed. The read disturb circuit 952 may instruct the reading circuit 954 to read the respective electric charge stored in each of the erased MLCs of a memory page or alternatively respective binary values corresponding to the electric charge stored in each of the erased MLCs of the erased memory page. Based on the binary values, read disturb detector 952 may determine the number of disturbed cells in a memory page. Utilizing previously described methods of FIG. 7 and FIG. 8, read disturb detector 952 may instruct the programming circuit to store received data at lower density that that of the MLCs of the erased memory page.

The memory system 900 may be implemented in many different ways. Each circuit, such as the read disturb detector 952, reading circuit 954, and programming circuit 956, may be hardware or a combination of hardware and software. For example, each module may include an application specific integrated circuit (ASIC), a Field Programmable Gate Array (FPGA), a circuit, a digital logic circuit, an analog circuit, a combination of discrete circuits, gates, or any other type of hardware or combination thereof. Alternatively or in addition, each circuit may include memory hardware, such as a portion of the controller ROM 206 (FIG. 2), for example, that comprises instructions executable with the processor 202 or other processor to implement one or more of the features of the circuit. When any one of the circuits includes the portion of the memory that comprises instructions executable with the processor, the module may or may not include the processor 202. In some examples, each circuit may just be the portion of the controller ROM 206 or other physical memory that comprises instructions executable with the processor 202 or other processor to implement the features of the corresponding module without the module including any other hardware. Because each circuit includes at least some hardware even when the included hardware comprises software, each circuit may be interchangeably referred to as hardware circuit, such as the read disturb detector 952, reading circuit 954, and programming circuit 956.

Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure.

In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate).

As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

By way of non-limiting example, in a three dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Then again, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

One of skill in the art will recognize that this invention is not limited to the two dimensional and three dimensional exemplary structures described but cover all relevant memory structures within the spirit and scope of the invention as described herein and as understood by one of skill in the art.

Further embodiments can be envisioned by one of ordinary skill in the art after reading the foregoing. In other embodiments, combinations or sub-combinations of the above disclosed invention can be advantageously made. The block diagrams of the architecture and flow diagrams are grouped for ease of understanding. However it should be understood that combinations of blocks, additions of new blocks, re-arrangement of blocks, and the like are contemplated in alternative embodiments of the present invention.

The specification and drawings are, accordingly, to be regarded in an illustrative rather than a restrictive sense. It will, however, be evident that various modifications and changes may be made thereunto without departing from the broader spirit and scope of the invention as set forth in the claims.

We claim:

1. A method for writing data in a memory system having a non-volatile memory, the method comprising:
identifying a memory page in the non-volatile memory that is erased, wherein the memory page comprises a set of memory cells and wherein the memory page is configured to store X times N bits of data where X is a number of memory cells comprising the memory page and where N is an integer number of bits that can be stored in each of the set of memory cells;
determining a number of read disturbed memory cells in the memory page, wherein a read disturbed memory cell contains an electric charge between a first and second predetermined threshold; and
in response to determining that the number of read disturbed memory cells of the memory page exceeds a threshold number, writing X times M bits of data to the memory page, wherein M is an integer and M<N and M>0.

2. The method of claim 1 further comprising:
identifying the memory page in response to receiving a request to write the data from a host device.

3. The method of claim 2 wherein determining the number of read disturbed memory cells comprising determining a respective voltage level from each of the memory cells wherein each of the respective voltage levels corresponds to the respective electric charge stored in each of the respective set of memory cells.

4. The method of claim 3 further comprising comparing each of the respective voltage levels with a first voltage threshold and a second voltage threshold and wherein the first predetermined threshold corresponds to the first voltage threshold and the second predetermined threshold corresponds to the second voltage threshold.

5. The method of claim 4 further comprising computing a fraction of the determined number of read disturbed memory cells and the number of memory cells.

6. The method of claim 5 wherein determining that the number of read disturbed memory cells of the memory page exceeds the threshold number comprises comparing the computed fraction with the threshold number wherein the threshold number is between 0 and 0.1.

7. A method for writing data in a memory system, the memory system comprising an erased memory page having a set of multi-layer cells (MLCs), wherein the set of MLCs have a first storage density, the method comprising:
in response to receiving a request to store data, determining a number of MLCs in the set of MLCs that exceed a voltage threshold; and
in response to determining that the number of MLCs exceeding the voltage threshold is above a threshold number of MLCs, storing a portion of the received data in the set of MLCs at a second storage density, wherein the second storage density is less than the first storage density.

8. The method of claim 7 further comprising receiving the request to write data from a host device.

9. The method of claim 7 further comprising identifying a second erased memory block to store a portion of the received data not stored in the erased memory block and storing the portion of the received data not stored in the erased memory block in the second erased memory block.

10. The method of claim 7 further comprising in response to determining that a number of MLCs in the set of MLCs exceeding a second voltage threshold is above the threshold number of MLCs, identifying a second erased memory page to store the data.

11. The method of claim 10 further comprising storing default data in the erased memory page.

12. The method of claim 7 wherein determining the number of MLCs in the set of MLCs that exceed the voltage threshold comprises determining a respective electric charge stored in each of the MLCs.

13. A device comprising:
a non-volatile memory having an erased memory page comprising a plurality of multi-layer cells (MLCs);
a reading circuit configured to read a respective electric charge stored in each of the plurality of MLCs of the erased memory page;
a programming circuit configured to store data in the plurality of MLCs at either one of a first storage density or a second storage density; and
a read disturb detector configured to, based on respective electric charges read from the MLCs, determine whether the erased memory page is read disturbed and, in response to determining that the erased memory page is read disturbed, cause the programming circuit to store data into the MLCs at the second storage density, wherein the second storage density is less than the first storage density.

14. The device of claim 13, wherein to determine whether the erased memory page is read disturbed, the read disturb detector is further configured to determine whether a number of MLCs in the plurality of MLCs having an electric charge exceeding a voltage threshold is above a threshold number of MLCs.

15. The device of claim 13, wherein the plurality of MLCs are adapted to store 3 bits of data per MLC and wherein the read disturb detector in response to determining that the erased memory page is read disturbed is configured to cause the programming circuit to store either 1 or 2 bits of data per MLC, wherein 3 bits of data per MLC corresponds to the first storage density and either 1 or 2 bits of data per MLC corresponds to the second storage density.

16. The device of claim 14 wherein to determine whether the erased memory page is read disturbed, the read disturb detector is further configured to determine whether a number of MLCs in the plurality of MLCs exceeding a second voltage threshold is above the threshold number of MLCs.

17. The device of claim 13 wherein the non-volatile memory comprises a three dimensional memory array.

18. The device of claim 13 further comprising a host device wherein the host device is configured to communicate data to be stored in the erased memory page.

19. The device of claim 14, wherein the read disturb detector is further configured to cause the programming circuit to store default data in the erased memory page when the number of MLCs in the plurality of MLCs exceeding a second voltage threshold is above the threshold number of MLCs.

20. The device of claim 19, wherein the read disturb detector is further configured to cause erasure of the erased memory page.
